(19) United States
(12) Patent Application Publication
(10) Pub. No.: US 2019/0280190 A1
(43) Pub. Date: Sep. 12, 2019

(54) METHOD FOR MANUFACTURING SEMICONDUCTOR DEVICE

(71) Applicant: KABUSHIKI KAISHA TOKAI RIKA DENKI SEISAKUSHO, Aichi (JP)

(72) Inventor: Takayuki HARA, Aichi (JP)

(73) Assignee: KABUSHIKI KAISHA TOKAI RIKA DENKI SEISAKUSHO, Aichi (JP)

(21) Appl. No.: 16/320,335

(22) PCT Filed: Jun. 12, 2017
(86) PCT No.: PCT/JP2017/021633

§ 371 Date: Jan. 24, 2019

(30) Foreign Application Priority Data
Jul. 28, 2016 (JP) 2016-148081

(51) Int. Cl. H01L 43/04; H01L 21/48; H01L 21/56; H01L 43/06; H01L 43/14

(52) U.S. Cl. CPC H01L 43/04; H01L 21/4825; H01L 43/14; H01L 21/565; H01L 43/06; H01L 21/4842

(57) ABSTRACT

A method for manufacturing a semiconductor device includes providing a lead frame including a plurality of circuit pattern forming regions that are arranged in rows, attaching electronic components to the circuit pattern forming region to form an electronic circuit unit, forming a first sealed body with a sealing resin such that the electronic circuit unit is covered and a plurality of outer leads are exposed, cutting off certain portions of a tie bar connecting the plurality of outer leads to thereby form anchor parts respectively on the outer leads, and also cutting off the plurality of outer leads and other tie bars connected to the lead frame to thereby from a primary molded body, and forming a secondary molded body by forming a second sealed body with a sealing resin so as to cover the anchor parts and the first sealed body of the primary molded body.

### TECHNICAL FIELD

The present invention relates to a method for manufacturing a semiconductor device.

### BACKGROUND ART

A semiconductor device is known, which is provided with a molded part encapsulating semiconductor chips, and lead terminals which are encapsulated, together with the semiconductor chips, in the molded part and are partially exposed from one surface of the molded part (see, e.g., JP 2015/95486 A).

In this semiconductor device, the lead terminals exposed from the molded part serve as connecting terminals which are connected to a connector, etc. Each connecting terminal has an anchor part located inside the molded part. To prevent the connecting terminals from slipping out of the molded part when the connecting terminals are pulled in an extending direction thereof, the width of the anchor parts is wide in a direction intersecting the pulling direction.

### CITATION LIST

### Patent Literature

JP 2015/95486 A

### SUMMARY OF INVENTION

### Technical Problem

It is an object of the invention to provide a method for manufacturing a semiconductor device, which can reduce the manufacturing cost by using a tie bar supporting outer leads to form anchor parts.

### Solution to Problem

In a method for manufacturing a semiconductor device in an embodiment of the invention, a semiconductor device is manufactured by: providing a lead frame comprising a plurality of circuit pattern forming regions that are arranged in rows; attaching electronic components to the circuit pattern forming region to form an electronic circuit unit; forming a first sealed body with a sealing resin such that the electronic circuit unit is covered and a plurality of outer leads are exposed; cutting off certain portions of a tie bar connecting the plurality of outer leads to thereby form anchor parts respectively on the outer leads, and also cutting off the plurality of outer leads and other tie bars connected to the lead frame to thereby from a primary molded body; and forming a secondary molded body by forming a second sealed body with a sealing resin so as to cover the anchor parts and the first sealed body of the primary molded body.

### Advantageous Effects of Invention

According to an embodiment of the invention, it is possible to provide a method for manufacturing a semiconductor device, which can reduce the manufacturing cost by using a tie bar supporting outer leads to form anchor parts.

### BRIEF DESCRIPTION OF DRAWINGS

FIG. 1A is a plan view showing a semiconductor device in an embodiment.

FIG. 1B is a plan view showing an example of a primary molded body of the semiconductor device.

FIG. 2 is a plan view showing a lead frame of the semiconductor device in the embodiment, on which a circuit pattern is formed.

FIG. 3A is a plan view showing a method for manufacturing the semiconductor device in the embodiment.

FIG. 3B is a plan view showing the method for manufacturing the semiconductor device in the embodiment.

FIG. 3C is a plan view showing the method for manufacturing the semiconductor device in the embodiment.

FIG. 3D is a plan view showing the method for manufacturing the semiconductor device in the embodiment.

FIG. 4A is a plan view showing anchor parts of the semiconductor device in a modification.

FIG. 4B is a plan view showing anchor parts of the semiconductor device in another modification.

FIG. 4C is a plan view showing anchor parts of the semiconductor device in yet another modification.

### DESCRIPTION OF EMBODIMENTS

### Summary of the Embodiment

A method for manufacturing a semiconductor device in the embodiment includes providing a lead frame comprising a plurality of circuit pattern forming regions that are arranged in rows; attaching electronic components to the circuit pattern forming region to form an electronic circuit unit, forming a first sealed body with a sealing resin such that the electronic circuit unit is covered and a plurality of outer leads are exposed, cutting off certain portions of a tie bar connecting the plurality of outer leads to thereby form anchor parts respectively on the outer leads, and also cutting off the plurality of outer leads and other tie bars connected to the lead frame to thereby from a primary molded body, and forming a secondary molded body by forming a second sealed body with a sealing resin so as to cover the anchor parts and the first sealed body of the primary molded body.

In the method for manufacturing a semiconductor device, the process of separating the primary molded body from the lead frame also forms the anchor parts. Since the tie bar supporting the outer leads is used to create the anchor parts, it is possible to reduce the manufacturing cost as compared to when this method is not employed.

### Embodiment

General Configuration of the Semiconductor Device 1

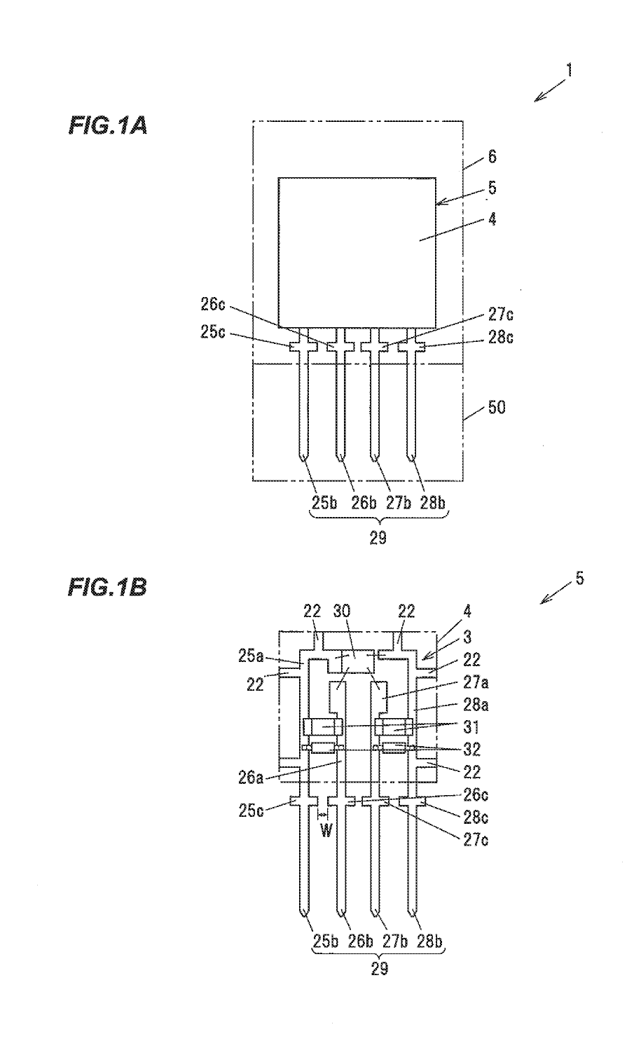

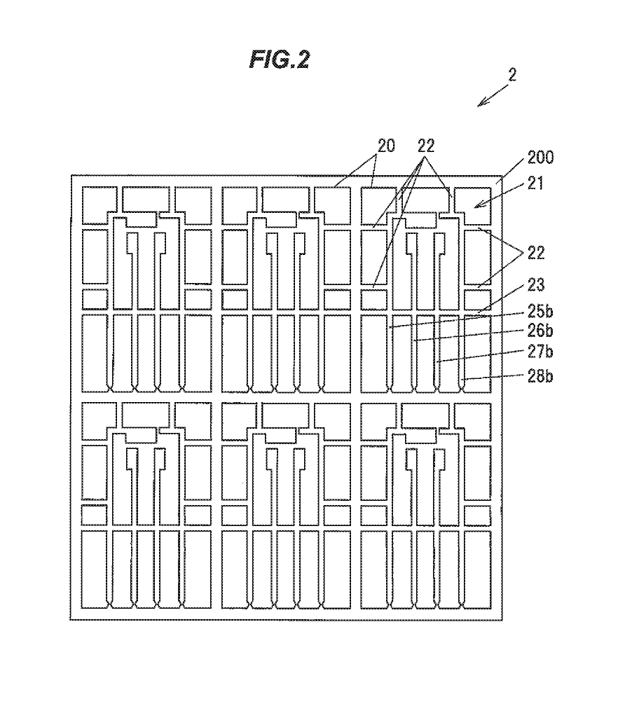

FIG. 1A is a plan view showing a semiconductor device in an embodiment and FIG. 1B is a plan view showing an example of a primary molded body of the semiconductor device. FIG. 2 is a plan view showing a lead frame of the semiconductor device in the embodiment, on which a circuit pattern is formed. In each drawing of the embodiment described below, a scale ratio may be different from an actual ratio.

The semiconductor device 1 in the present embodiment is, e.g., a magnetic sensor device provided with an electronic circuit unit 3 including a magnetic detection IC (Integrated Circuit) 30, as shown in FIGS. 1A and 1B. The semiconductor device 1, however, is not limited to the magnetic sensor device and may be, e.g., a pressure sensor device for detecting pressure, a temperature sensor device for measuring temperature, or a lighting device provided with light-emitting element.

The semiconductor device 1 is arranged on, e.g., a vehicle and is configured to detect approach of a detection target. Examples of the detection target include a brake pedal and a tongue plate of seat belt device.

To form the semiconductor device 1, a primary molded body 5 which is provided with a first sealed body 4 sealing the electronic circuit unit 3 is further sealed, as shown in FIGS. 1A and 1B. In other words, the semiconductor device 1 is formed by molding twice.

### Configuration of the Primary Molded Body 5

The primary molded body 5 is formed in, e.g., each of circuit pattern forming regions 20 of a lead frame 2, as shown in FIG. 2. The lead frame 2 is a thin plate formed of, e.g., a metal material such as aluminum, copper or iron, or an alloy material.

Plural circuit pattern forming regions 20 are formed on the lead frame 2, as shown in FIG. 2. A circuit pattern 21 according to the configuration of the magnetic detection IC 30 of the primary molded body 5 is formed in the circuit pattern forming region 20.

The circuit pattern 21 is to be a wiring of the electronic circuit unit 3 or a die pad on which electronic components are placed. The circuit pattern 21 is formed by punching (press cutting) or etching, etc.

The circuit pattern 21 is formed so that end portions of tie bars 22, a tie bar 23 and outer leads 25b-28b are connected to a frame 200 surrounding the circuit pattern forming region 20.

The tie bars 22 connect inner leads 25a-28a to the frame 200, as shown in FIG. 2. In other words, the inner leads 25a-28a are supported by the frame 200 via the plural tie bars 22.

The tie bar 23 intersects the outer leads 25b-28b aligned in a row and joins the frame 200 on both sides, as shown in FIG. 2. In other words, the outer leads 25b-28b are supported by the frame 200 via the tie bar 23.

End portions of the outer leads 25b-28b are tapered toward the tips which are connected to portions protruding from the frame 200. Since the protruding portions are also tapered in the same manner as the tips, the portions connected to the outer leads are the narrowest and thus can be cut easily.

The inner lead 25a and the outer lead 25b constitute a single lead formed by processing the lead frame 2. The inner lead 25a is sealed with the first sealed body 4. The outer lead 25b is exposed from the first sealed body 4. Likewise, each of the inner leads 26a-28a and the corresponding one of the outer leads 26b-28b constitute a single lead. The number of the leads is changed according to the configuration of the electronic circuit unit 3.

The electronic circuit unit 3 is formed by attaching electronic components onto the inner leads 25a-28a. The electronic circuit unit 3 in the present embodiment has the magnetic detection IC 30, two Zener diodes 31 and two capacitors 32 as the electronic components, as shown in FIG. 1B.

As an example, the magnetic detection IC 30 is arranged on the inner lead 25a using an adhesive such as silver paste. The magnetic detection IC 30 is electrically connected to the inner leads 25a-28a by a wire bonding method.

The magnetic detection IC 30 is provided with, e.g., a magnetic detection element, an amplifier for amplifying output of the magnetic detection element, and a control unit for determining approach of the detection target based on the amplified output. The magnetic detection element is constructed from, e.g., a Hall element which detects strength of a magnetic field generated by the detection target, or a magnetoresistive element which detects a change in a direction of the magnetic field.

The two Zener diodes 31 are electrically connected, e.g., between the inner lead 25a and the inner lead 26a and between the inner lead 27a and the inner lead 28a. Likewise, the two capacitors 32 are electrically connected, e.g., between the inner lead 25a and the inner lead 26a and between the inner lead 27a and the inner lead 28a. The Zener diodes 31 and the capacitors 32 form a protection circuit which protects the magnetic detection IC 30 from static electricity or noise, etc. The Zener diodes 31 are connected so that, e.g., voltage applied to the magnetic detection IC 30 is kept at a constant value. On the other hand, the capacitors 32 are connected so that, e.g., noise generated from the Zener diodes 31 is removed.

Anchor parts 25c-28c are respectively formed on the outer leads 25b-28b, as shown in FIG. 1B. The anchor parts 25c-28c are formed by cutting off certain portions of the tie bar 23 shown in FIG. 2. Thus, the anchor part 25c has a shape protruding in a direction intersecting a longitudinal direction of the outer lead 25b. Likewise, the other anchor parts 26c-28c have a shape protruding in a direction intersecting a longitudinal direction of the outer leads 26b-28b.

The anchor parts 25c-28c are sealed with a second sealed body 6, as shown in FIG. 1A. The anchor parts 25c-28c are provided to prevent the outer leads 25b-28b, when serving as the connecting terminals 29, from slipping out of the second sealed body 6 during insertion and removal of a connector.

The first sealed body 4 is formed by, e.g., molding a sealing resin. The sealing resin is a thermosetting molding material consisting mainly of an epoxy resin and containing a silicon filler, etc. The first sealed body 4 is formed to protect, e.g., the electronic circuit unit 3 from heat and moisture, etc.

### Configuration of the Second Sealed Body 6

The second sealed body 6 seals the primary molded body 5 so that the outer leads 25b-28b are partially exposed. The second sealed body 6 is formed of, e.g., a thermoplastic resin such as PE (polyethylene) or PP (polypropylene).

The second sealed body 6 is an exterior portion of the semiconductor device 1 and has a shape according to a place to attach. A connector portion 50 for inserting a connector to be connected is formed on the second sealed body 6. The connector portion 50 has a recessed shape into which the connector to be connected is inserted.

The outer leads 25b-28b are exposed, as the connecting terminals 29, inside the connector portion 50 formed on the second sealed body 6. In other words, the connecting terminals 29 are end portions of the outer leads 25b-28b which are exposed inside the connector portion 50.

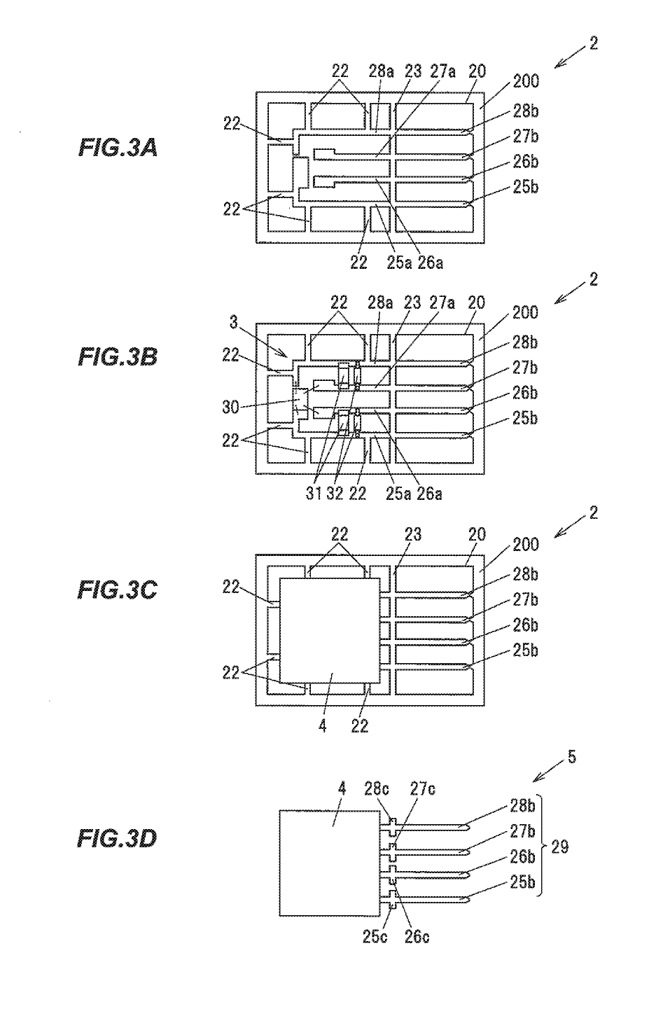

Next, an example of the method for manufacturing the semiconductor device 1 in the present embodiment will be described in reference to FIGS. 3A to 3D.

### Method for Manufacturing the Semiconductor Device 1

FIGS. 3A to 3D are explanatory plan views showing the method for manufacturing the semiconductor device in the embodiment. One circuit pattern forming region 20 is shown in FIGS. 3A to 3D.

The method for manufacturing the semiconductor device 1 includes: providing the lead frame 2 having plural circuit pattern forming regions 20 which are arranged in rows; attaching electronic components to the circuit pattern forming region 20 to form the electronic circuit unit 3; forming the first sealed body 4 with a sealing resin such that the electronic circuit unit 3 is covered and plural outer leads (the outer leads 25b-28b) are exposed; cutting off certain portions of the tie bar 23 connecting the plural outer leads to thereby form the anchor parts 25c-28c respectively on the outer leads, and also cutting off the plural outer leads and the other tie bars 22 connected to the lead frame 2 to thereby from the primary molded body 5; and forming a secondary molded body by forming the second sealed body 6 with a sealing resin so as to cover the anchor parts 25c-28c and the first sealed body 4 of the primary molded body 5.

In detail, firstly, the lead frame 2 having the plural circuit pattern forming regions 20 arranged in rows is provided as shown in FIG. 3A.

Next, as shown in FIG. 3B, the electronic circuit unit 3 is formed by attaching electronic components in the circuit pattern forming region 20. The electronic components are, e.g., the magnetic detection IC 30, the Zener diodes 31 and the capacitors 32.

Next, as shown in FIG. 3C, the first sealed body 4 formed of a sealing resin is provided so that the electronic circuit unit 3 is covered and the plural outer leads (the outer leads 25b-28b) are exposed. The sealing is performed in a state that the tie bars 22 and the tie bar 33 are connected to the frame 200 of the lead frame 2.

Next, as shown in FIG. 3D, certain portions of the tie bar 23 which connects the outer leads 25b-28b are cut off to form the anchor parts 25c-28c respectively on the outer leads, and at the same time, the other tie bars 22 and the outer leads 25b-28b, which are connected to the lead frame 2, are also cut off to form the primary molded body 5.

A width W of the portions to be cut off from the tie bar 23 to form the anchor parts 25c-28c is preferably small within a range in which respective insulation properties are maintained. This is because the anchor part has higher slip-off preventing performance when the protruding length from the outer lead is larger. The width W of the portions to be cut off is, e.g., about the same as the width of the outer lead.

Next, the secondary molded body is formed by forming the second sealed body 6 with a sealing resin so as to cover the anchor parts 25c-28c and the first sealed body 4 of the primary molded body 5, thereby obtaining the semiconductor device 1 shown in FIG. 1A.

### Modification

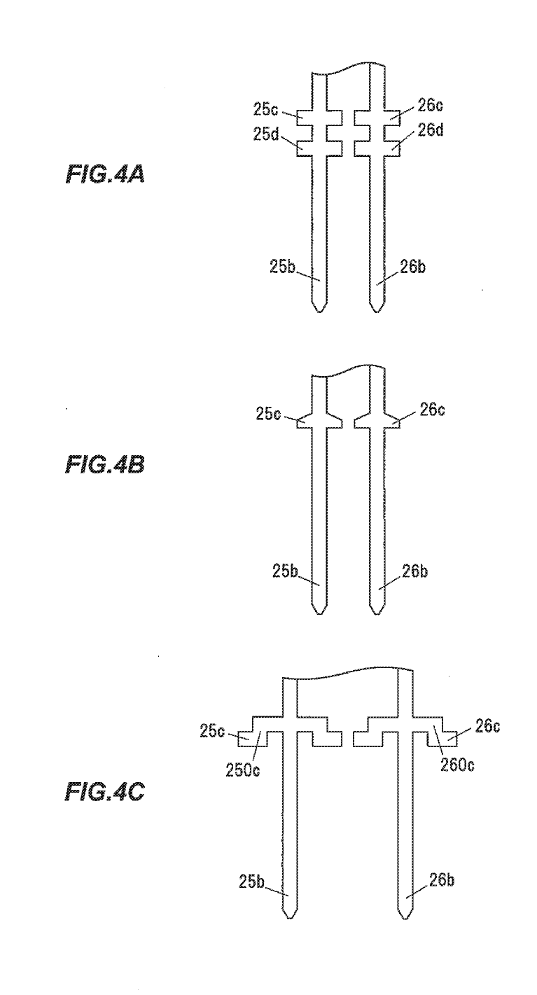

FIGS. 4A to 4C are plan views showing anchor parts of the semiconductor device in modifications. Some of the outer leads are shown in FIGS. 4A to 4C.

In one modification, plural anchor parts may be formed on one outer lead. In other words, plural tie bars 23 connecting the outer leads 25b-28b may be formed so that plural anchor parts are formed on each outer lead. In this modification, slipping out from the first sealed body 4 is prevented more than when one anchor part is provided.

FIG. 4A shows an example in which anchor parts 25c and 25d are formed on the outer lead 25b, and anchor parts 26c and 26d are formed on the outer lead 26b. In this regard, the anchor parts 25c and 26c located on the first sealed body 4 side may have a larger protruding length than the anchor parts 25d and 26d.

The shape of the anchor part is not limited to a rectangle. As another modification, for example, the anchor part may have a width which is larger on the outer lead side than on the tip side. In this modification, cutting off is easier and slipping out from the first sealed body 4 is prevented more than when this configuration is not employed. FIG. 4B shows an example in which the anchor parts 25c and 26c have a width which is larger on the outer lead side than on its tip end side.

As yet another modification, the anchor part may have a shape with a portion bent toward the tip of the outer lead. In this modification, slipping out from the first sealed body 4 is further prevented than when this configuration is not employed. FIG. 4C shows an example in which the anchor part 25c of the outer lead 25b has bent portions 250c bent in a direction toward the tip and the anchor part 26c of the outer lead 26b has bent portions 260c bent in a direction toward the tip.

### Effects of the Embodiment

In the method for manufacturing the semiconductor device 1 in the present embodiment, the tie bar 23 supporting the outer leads 25b-28b is used to form the anchor parts 25c-28c and this allows the manufacturing cost to be reduced. In detail, in the method for manufacturing the semiconductor device 1, the anchor parts 25c-28c are formed by cutting off certain portions of the tie bar 23 at the time of separating the primary molded body 5 from the lead frame 2. This means that, in the method for manufacturing the semiconductor device 1, the tie bar 23, which is completely removed by cutting off in the conventional technique, is partially left to form the anchor parts 25c-28c. Therefore, it is possible to reduce the manufacturing cost as compared to when this method is not employed.

The semiconductor device 1 has the anchor parts 25c-28c which are sealed with the secondary molded body. This prevents the outer leads 25b-28b from slipping out of the first sealed body 4 and improves reliability of the connecting terminals 29, as compared to when anchor parts are not provided.

Although the embodiment and some modifications of the invention have been described above, the embodiment and modifications are merely an example and the invention according to claims is not to be limited thereto. These new embodiment and modifications may be implemented in various other forms, and various omissions, substitutions and changes, etc., can be made without departing from the gist of the invention. In addition, all combinations of the features described in the embodiment and modifications are not necessary to solve the problem of the invention. Further, these embodiment and modifications are included within the scope and gist of the invention and also within the invention described in the claims and the equivalency thereof.

### REFERENCE SIGNS LIST

1 SEMICONDUCTOR DEVICE
2 LEAD FRAME
3 ELECTRONIC CIRCUIT UNIT
4 FIRST SEALED BODY
5 PRIMARY MOLDED BODY
6 SECOND SEALED BODY
20 CIRCUIT PATTERN FORMING REGION
23 TIE BAR
25b-28b OUTER LEAD
25c-28c ANCHOR PART
25d, 26d ANCHOR PART
29 CONNECTOR TERMINAL
50 CONNECTOR PORTION

1. A method for manufacturing a semiconductor device, comprising:
providing a lead frame comprising a plurality of circuit pattern forming regions that are arranged in rows;
attaching electronic components to the circuit pattern forming region to form an electronic circuit unit;
forming a first sealed body with a sealing resin such that the electronic circuit unit is covered and a plurality of outer leads are exposed;
cutting off certain portions of a tie bar connecting the plurality of outer leads to thereby form anchor parts respectively on the outer leads, and also cutting off the plurality of outer leads and other tie bars connected to the lead frame to thereby from a primary molded body; and
forming a secondary molded body by forming a second sealed body with a sealing resin so as to cover the anchor parts and the first sealed body of the primary molded body.

2. The method for manufacturing a semiconductor device according to claim 1, wherein the outer leads serve as connector terminals and are exposed inside a connector portion formed on the second sealed body.

3. The method for manufacturing a semiconductor device according to claim 1, wherein a plurality of tie bars are formed to connect the plurality of outer leads, and each of the outer leads comprises a plurality of anchor parts.

4. The method for manufacturing a semiconductor device according to claim 1, wherein a width of portions to be cut off from the tie bar connecting the plurality of outer leads is equal to a width of the outer leads.

5. The method for manufacturing a semiconductor device according to claim 1, wherein the anchor part is configured that the width is smaller at an end portion than a portion on the outer lead side.

6. The method for manufacturing a semiconductor device according to claim 1, wherein the anchor part comprises curved portions.

7. The method for manufacturing a semiconductor device according to claim 2, wherein a plurality of tie bars are formed to connect the plurality of outer leads, and each of the outer leads comprises a plurality of anchor parts.

8. The method for manufacturing a semiconductor device according to claim 3, wherein a width of portions to be cut off from the tie bar connecting the plurality of outer leads is equal to a width of the outer leads.

9. The method for manufacturing a semiconductor device according to claim 3, wherein the anchor part is configured that the width is smaller at an end portion than a portion on the outer lead side.

10. The method for manufacturing a semiconductor device according to claim 4, wherein the anchor part is configured that the width is smaller at an end portion than a portion on the outer lead side.

11. The method for manufacturing a semiconductor device according to claim 3, wherein the anchor part comprises curved portions.

12. The method for manufacturing a semiconductor device according to claim 4, wherein the anchor part comprises curved portions.
